(19) United States
(12) Patent Application Publication
(10) Pub. No.: US 2023/0371135 A1
(43) Pub. Date: Nov. 16, 2023

(54) VEHICULAR WINDOWPANE WITH METAL TERMINAL

(71) Applicant: AGC INC., Tokyo (JP)

(72) Inventors: Toru KOGA, Tokyo (JP); Nobutaka KOJIMA, Tokyo (JP)

(73) Assignee: AGC INC., Tokyo (JP)

(21) Appl. No.: 18/361,379

(22) Filed: Jul. 28, 2023

Related U.S. Application Data
(63) Continuation of application No. PCT/JP2022/003053, filed on Jan. 27, 2022.

(30) Foreign Application Priority Data
Feb. 1, 2021 (JP) 2021-014342

(51) Int. Cl. H05B 3/86; B60J 1/20; B32B 17/10; H01R 43/048; H01R 43/02

(52) U.S. Cl. CPC H05B 3/86; B60J 1/20; B32B 17/10385; H01R 43/048; H01R 43/02; H01R 2201/26

(57) ABSTRACT

A vehicle window glass with a metal terminal, includes a glass plate, an optically shielding layer on at least one of principal surfaces of the glass plate, a conductor on the optically shielding layer, a metal terminal electrically connected to the conductor via a lead-free solder, and a conductive wire fixed to the metal terminal; the metal terminal includes a pedestal portion electrically connected to a terminal connection portion via the lead-free solder; the conductor includes the terminal connection portion connected to the pedestal portion by means of a lead-free solder, and a coupling portion connected to the terminal connection portion with a narrow width than a width of the terminal connection portion in a longitudinal direction or a transverse direction of the terminal connection portion; the terminal connection portion and the coupling portion are connected together throughout at most 30% of an entire periphery of the terminal connection portion.

This application is a continuation of PCT Application No. PCT/JP2022/003053, filed on Jan. 27, 2022, which is based upon and claims the benefit of priority from Japanese Patent Application No. 2021-014342 filed on Feb. 1, 2021. The contents of those applications are incorporated herein by reference in their entireties.

### TECHNICAL FIELD

The present invention relates to a vehicle window glass with a metal terminal.

### BACKGROUND ART

Vehicle window glasses have a heating member made of a conductor and disposed on a glass plate for e.g., defogging or deicing in some cases. Vehicle window glasses have an antenna made of a conductor and disposed on a glass plate for a radio receiver, a TV receiver, wireless communication or a sensor in some cases.

The conductor on a vehicle window glass is electrically connected to a metal terminal via a solder to be energized, or to receive or transmit e.g., a signal. The metal terminal is fixed to a conductive wire electrically connected to a power source or a signal source, which is disposed in the vehicle. The conductor has been connected to the metal terminal by means of a leaded solder. The leaded solder can relax a residual stress easily during soldering because of having excellent solderability and good plastic deformability. From this point of view, the conductor on the glass plate can be easily connected to the metal terminal by means of a leaded solder. Nevertheless, it has been recently pointed out that lead has an adverse effect on human bodies or environments. It has been desired to use a lead-free solder for vehicle window glasses.

For example, Patent Document 1 listed below discloses a vehicle window glass with a metal terminal, which includes a glass substrate, an electrically conductive layer on the glass substrate, and a metal terminal connected by means of a lead-free solder on the electrically conductive layer. Patent Document 2 listed below discloses that when a metal terminal is connected to a terminal connection portion (conductor) on a glass plate by means of a lead-free solder in a vehicle glass window with a metal terminal, a residual stress is caused in the glass plate by temperature changes in the glass plate during soldering to easily crack a surface of the glass plate because the lead-free solder has a higher elastic modulus than the leaded solder due to the absence of lead having a low elastic modulus, resulting in that the stress caused by the temperature changes is likely to be made large. Regarding the crack in a glass plate caused by a residual stress in the glass plate, Patent Document 2 also discloses that the glass plate can be preheated to reduce the residual stress in the glass plate when the metal terminal is soldered to a conductor disposed on the glass plate.

### PRIOR ART DOCUMENTS

### Patent Documents

Patent Document 1: JP-A-2018-159128
Patent Document 2: Japanese Patent No. 6186725

### DISCLOSURE OF INVENTION

### Technical Problem

The vehicle window glasses with a metal terminal are normally configured to include an optically shielding layer disposed on a principal surface of a glass plate, and a conductor disposed on the optically shielding layer such that the conductor is connected to a metal terminal by means of a lead-free solder. By the way, in addition to the crack (initial crack) caused by a residual stress in a glass plate generated by a temperature change of the glass plate during soldering of a metal terminal, an optically shielding layer disposed on a principal surface of the glass plate or a conductor disposed on the optically shielding layer could be cracked, starting at a physically weak portion of the optically shielding layer or the conductor in several days after the soldering of the metal terminal. The crack caused in the optically shielding layer or the conductor could cause the glass plate to have a surface under the optically shielding layer partially peeling off.

The present invention has been proposed in consideration of the problem. It is an object of the present invention to provide a vehicle window glass with a metal terminal, which is capable of not only reducing the occurrence of a crack in an optically shielding layer disposed on a principal surface of a glass plate or a conductor disposed on the optically shielding layer but also preventing a surface of the glass plate under the optically shielding layer from being partially peeled off by the crack caused in the optically shielding layer or the conductor even in several days after the conductor is connected to a metal terminal by a lead-free soler.

### Solution to Problem

The vehicle window glass with a metal terminal according to one aspect of the present invention includes a glass plate, an optically shielding layer disposed on at least one of principal surfaces of the glass plate, a conductor disposed on the optically shielding layer, a metal terminal electrically connected to the conductor via a lead-free solder, and a conductive wire configured to be fixed to the metal terminal; wherein the metal terminal includes a pedestal portion connected to a terminal connection portion; wherein the conductor includes the terminal connection portion connected to the pedestal portion by means of the lead-free solder, and a coupling portion connected to the terminal connection portion and having a narrower width than a width of the terminal connection portion in a longitudinal direction or a transverse direction of the terminal connection portion; wherein the terminal connection portion and the coupling portion are connected together throughout at most 30% of an entire periphery of the terminal connection portion as seen in plan view; and wherein the terminal connection portion has an edge located less than 3 mm away from a pedestal edge forming the pedestal portion in a direction away from the pedestal portion.

### Advantageous Effects of Invention

The vehicle window glass with a metal terminal according to the one aspect of the present invention can not only reduce the occurrence of a crack in an optically shielding layer disposed on the principal surface of a glass plate or a conductor disposed on the optically shielding layer but also prevent a surface of the glass plate under the optically shielding layer from peeling off.

### BRIEF DESCRIPTION OF DRAWINGS

FIG. 1 is a perspective view of the metal terminal according to an embodiment.

FIG. 2 is a perspective view of the vehicle window glass with a metal terminal according to a basic embodiment, the vehicle window including the metal terminal shown in FIG. 1.

FIG. 3 is a plan view of the conductor disposed on the glass plate according to a first embodiment of the present invention.

FIG. 4 is a plan view illustrating how the metal terminal according to the first embodiment is connected to the conductor.

FIG. 5 is an enlarged plan view of the first embodiment.

FIG. 6 is a cross-sectional view taken along line VI-VI of FIG. 5.

FIG. 7 includes FIGS. 7A to 7F, which are plan views illustrating some modifications of the first embodiment.

FIG. 8 includes FIGS. 8G to 81, which are plan views illustrating other modifications of the first embodiment.

FIG. 9 is an enlarged view of a second embodiment of the present invention.

FIG. 10 is a cross-sectional view taken along line X-X of FIG. 9.

FIG. 11 includes FIGS. 11A to 11F, which are plan views illustrating some modifications of the second embodiment.

FIG. 12 includes FIGS. 12G to 121, which are plan views illustrating other modifications of the second embodiment.

FIG. 13 is an enlarged view of a third embodiment.

FIG. 14 is a cross-sectional view taken along line XIV-XIV of FIG. 13.

FIG. 15 includes FIGS. 15A to 15F, which are plan views illustrating some modifications of a third embodiment.

FIG. 16 includes FIGS. 16G to 16I, which are plan views illustrating other modifications of the third embodiment.

FIG. 17 includes FIGS. 17A and 17B, which are plan views illustrating some modifications of a fourth embodiment.

FIG. 18 is a perspective view illustrating other modifications of the vehicle window glass with a metal terminal.

### DESCRIPTION OF EMBODIMENTS

Now, some embodiments of the vehicle window glass with a metal terminal according to the present invention will be described in reference to the accompanying drawings. The members and parts exemplified in the embodiments are merely examples. The scope of the invention is not limited to these embodiments.

Metal Terminal

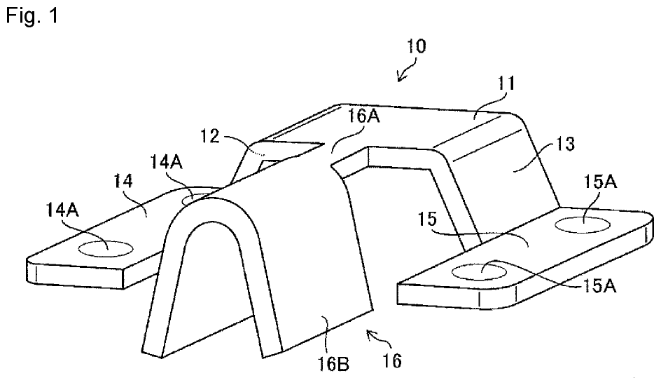

The metal terminal attached to a vehicle window glass with a metal terminal will be described based on the accompanying drawings. FIG. 1 is a perspective views of the metal terminal according to an embodiment.

As shown in FIG. 1, the metal terminal 10 includes a leg connection portion 11, a first leg portion 12 connected to the leg connection portion 11, a first pedestal portion 14 connected to the first leg portion 12, a second leg portion 13 connected to the leg connection portion 11, and a second pedestal portion 15 connected to the second leg portion 13. The first leg portion 12 and the second leg portion 13 have a function of separating the leg connection portion 11 from a conductor. The metal terminal 10 may also include a conductive wire coupling portion 16. The leg connection portion 11 connects the first leg portion 12, the second leg portion 13 and the wire connection portion 16.

The leg connection portion 11 has a top surface formed in a substantially rectangular shape so as to have two longer sides and two shorter sides. The two longer sides are in substantial parallel to each other. The two shorter sides are in substantial parallel to each other. The first leg portion 12 and the second leg portion 13 are respectively connected to the different shorter sides of the leg connection portion 11. Each of the first leg portion 12 and the second leg portion 13 has a width equal to the length of the shorter sides.

The first pedestal portion 14 projects in a width direction of the first leg portion 12. Likewise, the second pedestal portion 15 projects in a width direction of the second leg portion 13. Each of the first pedestal portion 14 and the second pedestal portion 15 is longer than the shorter sides of the leg connection portion 11.

The first pedestal portion 14 and the second pedestal portion 15 are electrically connected, via a solder, to the conductor disposed on a glass plate. The first pedestal portion 14 has two dents 14A formed thereon. The formation of the dents 14A forms bulges on a surface of the first pedestal portion opposite to the surface of the first pedestal portion where the dents 14A are formed. Likewise, the second pedestal portion 15 has two dents 15A formed thereon. The formation of the dents 15A forms bulges on a surface of the second pedestal portion opposite to the surface of the second pedestal portion where the dents 15A are formed. It should be noted that the number of the dents 14A and the number of the dents 15A are not limited to two.

The conductive wire coupling portion 16 includes an extending portion 16A connected to the leg connection portion 11, and a fixing portion 16B connected to the extending portion 16A. The extending portion 16A is connected to a longer side of the leg connection portion 11 so as to be flush with the leg connection portion 11. The extending portion 16A extends in the same direction as projecting portions of the first pedestal portion 14 and the second pedestal portion 15.

The fixing portion 16B has a function of fixing a conductive wire. In this embodiment, the fixing portion 16B is formed as a caulking portion. The caulking portion includes a pair of opposed wall portions and a wall connection portion connecting edges of the paired wall portions. The caulking portion is formed in a U shape in front view as seen in a direction opposite to the extending portion 16A. The caulking portion in a U shape is open toward a side where the first pedestal portion 14 and the second pedestal portion 15 are disposed. It should be noted that the caulking portion in a U shape may be open toward a side opposite to the side where the first pedestal portion 14 and the second pedestal portion 15 are disposed. The fixing portion 16B may be formed as a soldering portion or welding portion instead of the caulking portion.

The metal terminal 10 contains at least one metal selected from the group consisting of copper, brass, iron, chromium, and an alloy including copper, brass, iron and chromium. The metal terminal 10 may be subjected to surface treatment (such as tin plating) as required. The metal terminal 10 may have a thickness of preferably at least 0.4 mm and at most 0.8 mm. The metal terminal 10 may be prepared by pressing or bending a metal plate.

Each of the fixing portion 16B and a portion of the conductive wire to be fixed to the fixing portion 16B may be covered by a protection member made of an insulator. The insulator may be made of an insulting material, such as an insulating resin. The resin is preferably made of a material having excellent flexibility. There is no particular limitation to the kind of the resin. As the resin, polyvinylchloride, a fluororesin, natural rubber, synthetic rubber, polyethylene terephthalate, polyolefin, or polyimide may be applicable for example. Each of the fixing portion 16B and a portion of the conductive wire to be fixed to the fixing portion 16B is preferably covered by a protection member made of an insulator. In this case, even when an external force is applied to the metal terminal 10 or the conductive wire to deform the metal terminal 10, causing the metal terminal to be brought into direct contact with the vehicle window glass or a vehicle body made of metal, the provision of the protection member prevents scratching of the vehicle window glass or short-circuiting with the vehicle body, which is advantageous.

Vehicle Window Glass with Metal Terminal

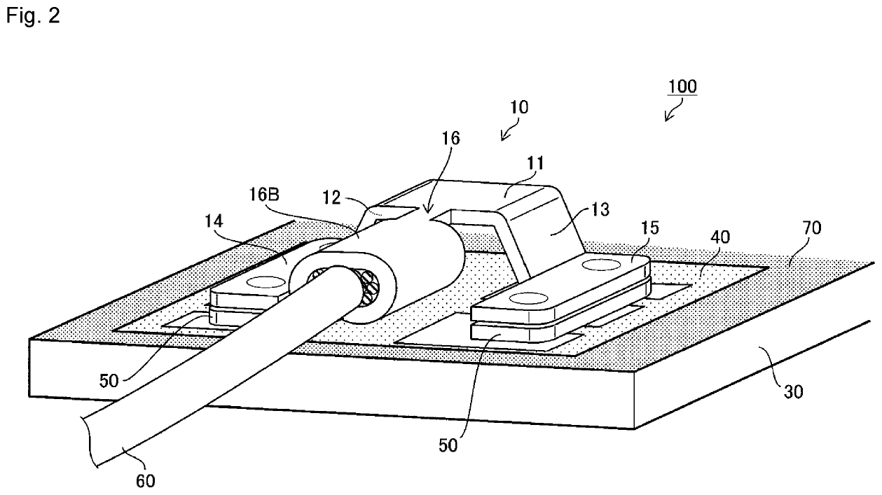

The vehicle window glass with a metal terminal will be described based on the accompanying drawings. FIG. 2 is a perspective view of the vehicle window glass with a metal terminal according to a basic embodiment.

The vehicle window glass with a metal terminal 100 shown in FIG. 2 includes a glass plate 30, a conductor 40 disposed on at least one of principal surfaces of the glass plate 30, and a metal terminal 10 electrically connected to the conductor 40 via a solder 50. In FIG. 2, it is shown that the at least one principal surface of the glass plate 30 has an optically shielding layer 70 disposed thereon, and that the conductor 40 is disposed on the optically shielding layer 70.

The glass plate 30 may be made of, e.g., soda-lime glass, borosilicate glass, alkali-free glass or quartz glass without any limitation. Among them, soda-lime glass may be particularly preferable. The glass plate 30 may be made of either non-tempered glass or tempered glass. The non-tempered glass is one that is produced by forming molten glass in a plate shape and annealing the formed molten glass. The tempered glass is one that is produced by forming a compressive stress layer in the surface of non-tempered glass. The tempered glass may be either physically tempered glass (such as glass tempered by air quenching), or chemically tempered glass. When the glass plate 30 is made of physically tempered glass, the glass surface may be tempered by quenching a uniformly heated glass plate from a temperature close to its softening point such that a temperature difference is generated between the glass surface and the inside of the glass to form a compressive stress in the glass surface. In contrast, when the glass plate 30 is made of chemically tempered glass, the glass surface may be tempered by causing a compressive stress in the glass surface by ion exchange treatment or the like. Although the glass plate may be preferably transparent, a glass plate that is colored to such a degree not to impair transparency may be used. Although there is no particular limitation to the thickness of the glass plate 30, the glass plate may have a thickness of preferably at least 0.5 mm and at most 5.0 mm.

The conductor 40 may be formed by, e.g., baking conductive silver paste (made of a material having an electrical resistivity of 0.5 to 9.0×10⁻⁸ Ω·m) after printing or applying the conductive silver paste on the at least one principal surface of the glass plate 30. The conductor 40 may have a thickness of preferably at least 3 μm and at most 15 μm, more preferably at least 3 μm and at most 10 μm.

The solder 50 is made of a lead-free solder. The lead-free solder is a solder containing almost no lead. Although there is no particular limitation to the kind of the lead-free solder, the lead-free solder may preferably contain Sn (tin) and Ag (silver), such as a Sn—Ag solder, a Sn—Ag—In solder, a Sn—Ag—Al—Zn solder, a Sn—Al—In—Ag—Cu—Zn solder, or a Sn—Ag—Cu solder. In this case, the lead-free solder may have an Sn (tin) content of preferably at least 95 mass %.

The metal terminal 10 is disposed, via the solder 50, on the conductor 40 disposed on the glass plate 30. The first pedestal portion 14 and the second pedestal portion 15 of the metal terminal 10 may be electrically connected to the conductor 40 via the solder 50. The first leg portion 12 and the second leg portion 13 separate the leg connection portion 11 from the conductor 40.

In this basic embodiment, the conductive wire coupling portion 16 is directed in a direction for the conductive wire 60 to extend.

The conductive wire 60 may be fixed to the fixing portion 16B of the conductive wire coupling portion 16 by caulking. The conductive wire 60 may be made up of a core wire and an insulator covering the core wire. The core wire may be exposed from the insulator at one end of the conductive wire 60 and is caulked by the fixing portion 43. Thus, the conductive wire 60 and the conductor 40 are electrically connected together via the metal terminal 10 and the solder 50.

The core wire may be made of, e.g., metal. Although there is not particular limitation to the kind of the metal, gold, silver, nickel, copper, aluminum, tin, cobalt, or an alloy containing at least one element among them may be applicable for example. The core wire may be a single linear conductor or a bundle of plural linear conductors. The core wire has a diameter of approximately 2 mm to 8 mm, which is not essential. The insulator may be made of an insulating material, such as an insulating resin. The resin may be preferably made of a material having excellent flexibility. Although there is no particular limitation to the kind of the insulating resin, polyethylene terephthalate, polypropylene, polyethylene or polyimide may be applicable for example.

The metal terminal 10 is preferably disposed on an inner side of the glass plate when the vehicle window glass with a metal terminal 100 is mounted to a vehicle.

The optically shielding layer 70 may be dark and opaque, such as black. The optically shielding layer 70 may have a function of protecting, e.g., a urethane sealant or the like from being deteriorated by ultra violet light. The optically shielding layer 70 may be disposed by, e.g., baking ceramic paste after applying the ceramic paste on the glass plate 30. The optically shielding layer 70 may have a thickness of at least 3 μm and at most 15 μm. Although there is no particular limitation to the width of the optically shielding layer 70, the optically shielding layer may have a width of preferably at least 20 mm and at most 300 mm.

Now, the relationship between the conductor 40 and the pedestal portions (including the first pedestal portion 14 and the second pedestal portion 15) will be described.

The inventors of the present invention have investigated that in addition to a crack (initial crack) caused by a residual stress in a glass plate generated by a temperature change of the glass plate during soldering of a metal terminal, an optically shielding layer formed on the glass plate or a conductor disposed on the optically shielding layer could be cracked, starting at a physically weak portion of the optically shielding layer or the conductor in several days after the metal terminal is soldered to the conductor via a lead-free solder, with the result that the glass plate has a surface under the optically shielding layer partially peeling off. As a result of the investigation, the inventors have achieved the present invention, finding out that not only the spreading of the lead-free solder but also the sizes of the conductor 40 and the pedestal portions are related to the occurrence of a crack in the optically shielding layer or the conductor, which starts at a physically weak portion of the optically shielding layer or the conductor in several days after the metal terminal is connected, by means of the lead-free solder, to the conductor disposed on the optically shielding layer.

### First Embodiment

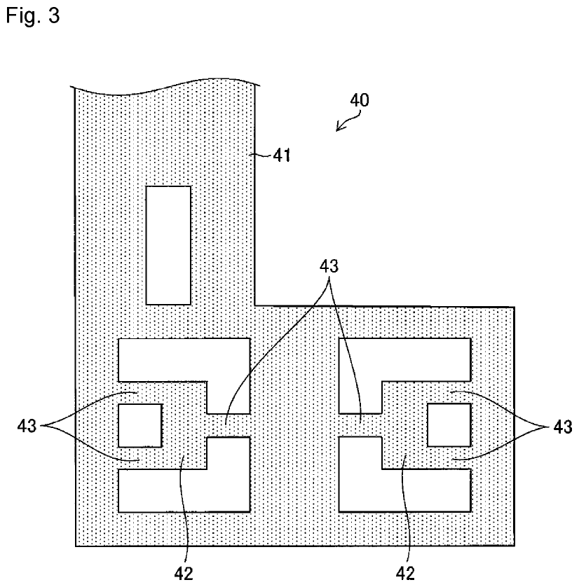

The vehicle window glass with a metal terminal according to a first embodiment of the present invention will be described. FIG. 3 is a plan view of a conductor 40 disposed on a glass plate 30. The conductor 40 includes a bus bar portion 41, a terminal connection portion 42, and three coupling portions 43 connecting between the bus bar portion 41 and the terminal connection portion 42 for each of first and second pedestal portions of a metal terminal. The bus bar portion 41, the terminal connection portion 42 and the coupling portions 43 are electrically connected together.

The bus bar portion 41 of the conductor 40 has a greater width than at least one portion of the coupling portions 43. The width of the bus bar portion 41 can become greater, reducing the electrical resistance and decreasing the temperature rises during energization.

In FIG. 3, the respective terminal connection portions 42 are electrically connected, via a lead-free solder, to the first pedestal portion 14 and the second pedestal portion 15 (not shown in this figure), respectively. The terminal connection portions 42 and the bus bar portion 41 conduct power supply, or perform reception and transmission or another operation from the metal terminal 10 (not shown) via the coupling portions 43.

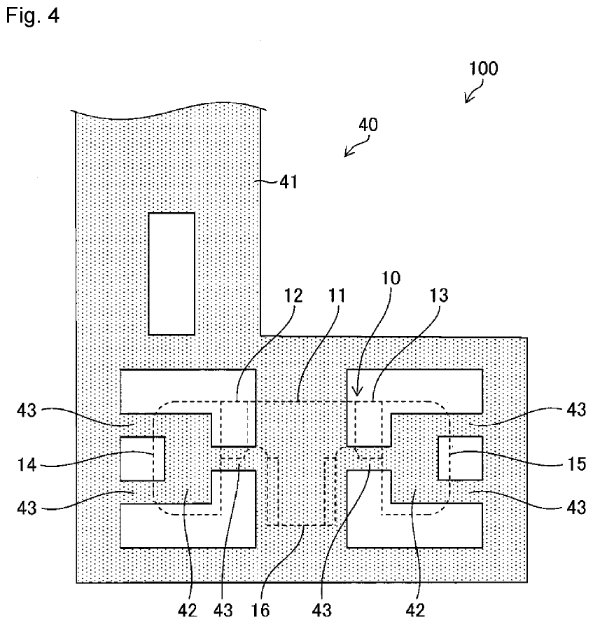

FIG. 4 is a plan view illustrating how the metal terminal 10 (shown in dotted lines) is connected to the conductor 40. As shown in FIG. 4, the first pedestal portion 14 and the second pedestal portion 15 are connected to areas of the terminal connection portions 42 via the solder 50 (not shown in this figure).

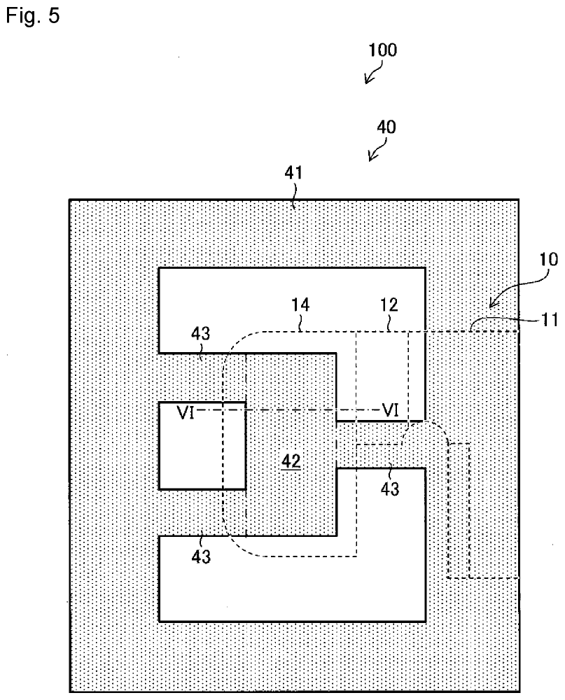

FIG. 5 is an enlarged plan view of FIG. 4. In FIG. 5, the metal terminal 10 has an outline indicated in dotted lines. The conductor 40 includes a terminal connection portion 42, two coupling portions 43 connected to one of the opposite longer sides of the terminal connection portion 42, and a coupling portion 43 connected to the other longer side for each of the pedestal portions. The conductor 40 includes the three coupling portions 43 in total for each of the pedestal portions. The three coupling portions 43 have the same width as one another.

Each terminal connection portion 42 has a shape delimited by its edge as seen in plan view. In the first embodiment, each terminal connection portion 42 is determined to be formed in such a substantially rectangular shape that the edge includes four linear edge sections. The edge may not only include linear edge sections but also be curved or be made up of a combination of a linear edge section and a curved edge section.

The edge of each terminal connection portion 42 includes edge sections out of connection with the coupling portions 43. Visually recognized edge sections serve as elements determining the shape of each terminal connection portion 42. In positions where each terminal connection portion 42 is connected to the related coupling portions 43, imaginary lines (shown in two-dot chain lines) as extension of the related visually recognized edge section or edge sections form parts of the edge, also serving as elements determining the shape of the terminal connection portion 42. Each terminal connection portion 42 has an entire periphery delimited by the continuous edge including the imaginary lines.

As shown in FIG. 5, the coupling portions 43 have a narrower width than the width of the terminal connection portion 42 in a longitudinal direction or a transverse direction. The longitudinal direction is a first direction as seen in plan view while the transverse direction is a second direction orthogonal to the longitudinal direction. The width is a distance between opposed edge sections. The coupling portions 43 may include at least one narrower width than the width of the terminal connection portion 42 in the longitudinal direction or the transverse direction.

The first pedestal portion 14 is formed in a shape delimited by its pedestal edge as seen in plan view. In the first embodiment, the shape of the first pedestal portion 14 is delimited by four linear edge sections and two arc edge sections. The pedestal edge of the first pedestal portion may be linear, curved or made up of a combination of a linear edge section and a curved edge section.

The pedestal edge of the first pedestal portion 14 is located outside the edge of the terminal connection portion 42. This means that the terminal connection portion 42 is smaller than the first pedestal portion 14.

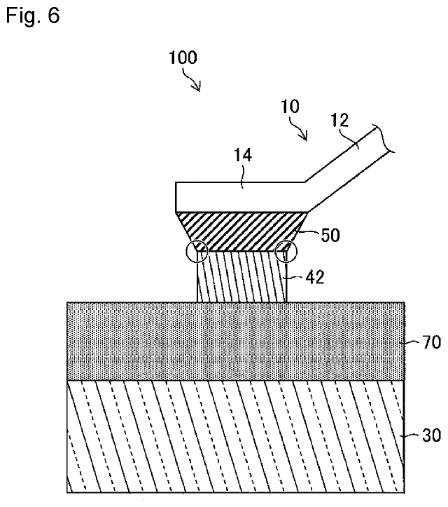

FIG. 6 is a cross-sectional view taken along line VI-VI of FIG. 5. In FIG. 6, it is shown that the vehicle window glass with a metal terminal 100 includes a glass plate 30, an optically shielding layer 70 disposed on the glass plate 30, a terminal connection portion 42, and the first pedestal portion 14 of the metal terminal 10, which is electrically connected to the terminal connection portion 42 via the solder 50.

The solder 50 is formed in a substantially trapezoidal shape having a shorter bottom than a top as seen in cross-section since the pedestal edge of the first pedestal portion 14 is located outside the edge of the terminal connection portion 42. As shown in circles in FIG. 6, the edge of the terminal connection portion 42 can conform to the edge of the solder 50, resulting in that the optically shielding layer 70 or the conductor 40 disposed on the optically shielding layer 70 can be prevented from being cracked in several days after the metal terminal 10 is connected, by means of the lead-free solder, to the conductor 40. In other words, the edge of the terminal connection portion 42 can conform to the edge of the solder 50 to prevent a crack from starting easily at the optically shielding layer 70 or the conductor 40, resulting in that a surface of the glass plate 30 under the optically shielding layer 70 is prevented from partially peeling off.

It is supposed that the solder 50 could flow beyond the edge of the terminal connection portion 42 along the coupling portions 43 at portions where the terminal connection portion 42 is connected to the coupling portions 43 shown in FIG. 5. In this case, it is difficult to cause the edge of the solder 50 to conform to the edge of the terminal connection portion 42. From this point of view, in the first embodiment, the terminal connection portion 42 is connected to the coupling portions 43 throughout at most 30% of the entire periphery of the terminal connection portion 42 as seen in plan view. The terminal connection portion 42 can be connected to the coupling portions 43 throughout at most 30% of the entire periphery of the terminal connection portion 42 to increase the area where the edge of the solder 50 is caused to conform to the edge of the terminal connection portion 42. Further, the terminal connection portion 42 can be connected to the coupling portions 43 throughout at most 30% of the entire periphery of the terminal connection portion 42 to secure a required bonding strength between the metal terminal 10 and the conductor 40.

By calculating the formula of (L2/L1)×100 wherein the entire periphery of the terminal connection portion 42 (including visually recognized edge sections and the two-dot chain lines) is L1, and the coupled portions between the terminal connection portion 42 and the coupling portions 43 has a length L2 (the length of the two-dot chain lines only), it may be determined whether to meet the requirement of at most 30% of the entire periphery of the terminal connection portion 42.

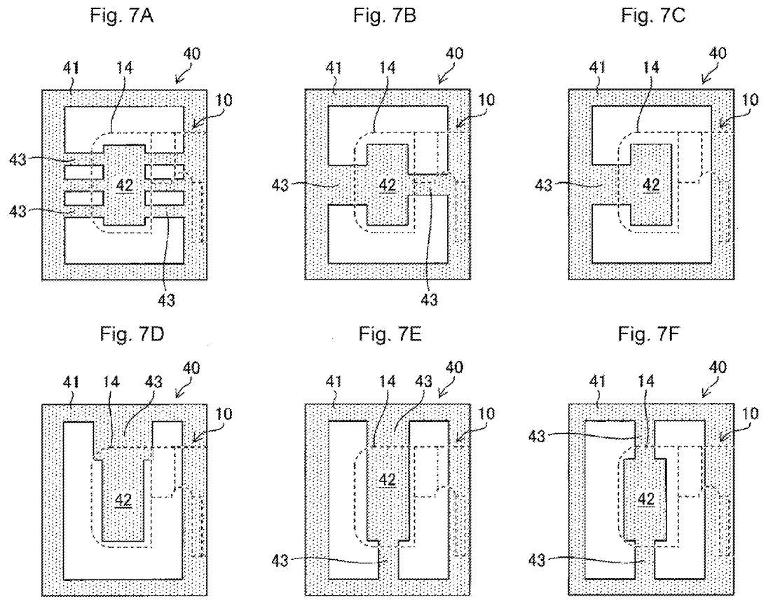

FIGS. 7A to 7F and FIGS. 8G to 81 are plan views illustrating modifications of the first embodiment. In each of the modifications shown in FIGS. 7A to 7F and FIGS. 8G to 81, the pedestal edge of the first pedestal portion 14 is located outside the edge of the terminal connection portion 42.

In the modification shown in FIG. 7A, the conductor 40 includes a bus bar portion 41, a terminal connection portion 42, and three coupling portions 43 connected to each of the opposite longer sides of the terminal connection portion 42. The conductor 40 includes the six coupling portions 43 in total. The six coupling portions 43 have the same width as one another.

In the modification shown in FIG. 7B, the conductor 40 includes a bus bar portion 41, a terminal connection portion 42, and a coupling portion 43 connected to each of the opposite longer sides of the terminal connection portion 42. The conductor 40 includes the two coupling portions 43 in total. The two coupling portions 43 have different widths from each other.

In the modification shown in FIG. 7C, the conductor 40 includes a bus bar portion 41, a terminal connection portion 42, and a single coupling portion 43 connected to a longer side of the terminal connection portion 42.

In the modification shown in FIG. 7D, the conductor 40 includes a bus bar portion 41, a terminal connection portion 42, and a single coupling portion 43 connected to a shorter side of the terminal connection portion 42.

In the modification shown in FIG. 7E, the conductor 40 includes a bus bar portion 41, a terminal connection portion 42, and a coupling portion 43 connected to each of the opposite shorter sides of the terminal connection portion 42. The conductor 40 includes the two coupling portions 43 in total. The two coupling portions 43 have different widths from each other.

In the modification shown in FIG. 7F, the conductor 40 includes a bus bar portion 41, a terminal connection portion 42, and a coupling portion 43 connected to each of the opposite shorter sides of the terminal connection portion 42. The conductor 40 includes the two coupling portions 43 in total. The two coupling portions 43 have the same width as each other.

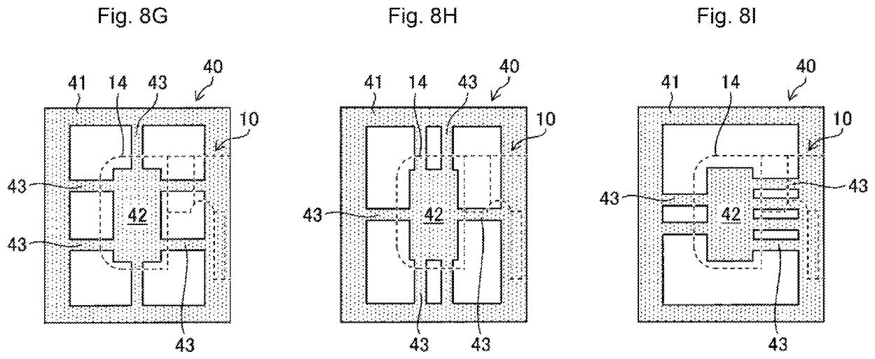

In the modification shown in FIG. 8G, the conductor 40 includes a bus bar portion 41, a terminal connection portion 42, two coupling portions 43 connected to each of the opposite longer sides of the terminal connection portion 42, and a coupling portion 43 connected to each of the opposite shorter sides of the terminal connection portion 42. The conductor 40 includes the six coupling portions 43 in total. The six coupling portions 43 have the same width as one another.

As shown in FIG. 8H, the conductor 40 may include a bus bar portion 41, a terminal connection portion 42, two coupling portions 43 connected to each of the opposite shorter sides of the terminal connection portion 42, and a coupling portion 43 connected to each of the opposite longer sides of the terminal connection portion 42. The conductor 40 includes the six coupling portions 43 in total. The six coupling portions 43 have the same width as one another.

In the modification shown in FIG. 8I, the conductor 40 includes a bus bar portion 41, a terminal connection portion 42, two coupling portions 43 connected to one of the opposite longer sides of the terminal connection portion 42, and four coupling portions 43 connected to the other longer side of the terminal connection portion 42. The conductor 40 includes the six coupling portions 43 in total. The six coupling portions 43 have the same width as one another.

The terminal connection portions 42 according to the respective modifications shown in FIGS. 7A to 7F and FIGS. 8G to 81 have the same area as one another. The coupling portions according to the respective modifications shown in FIGS. 7A to 7F and FIGS. 8G to 8I have the same total area as one another.

Regarding each of the modifications shown in FIG. 4 to FIG. 8I, the first pedestal portion 14 has been described. The explanation of the first pedestal portion 14 according to each of the modifications is also applicable to the second pedestal portion 15. The explanation of the first pedestal portion 14 according to each of the modifications is also applicable to a metal terminal including a single pedestal portion or at least three pedestal portions, which is different from the metal terminal 10 including the two pedestal portions (the first pedestal portion 14 and the second pedestal portion 15).

The coupling structure between the terminal connection portion 42 and the coupling portion or portions 43 is not limited to the examples shown in FIGS. 7A to 7F and FIG. 8G to FIG. 8I and may be properly modified so long as the pedestal edge of the first pedestal portion 14 is located outside the edge of the terminal connection portion 42.

### Second Embodiment

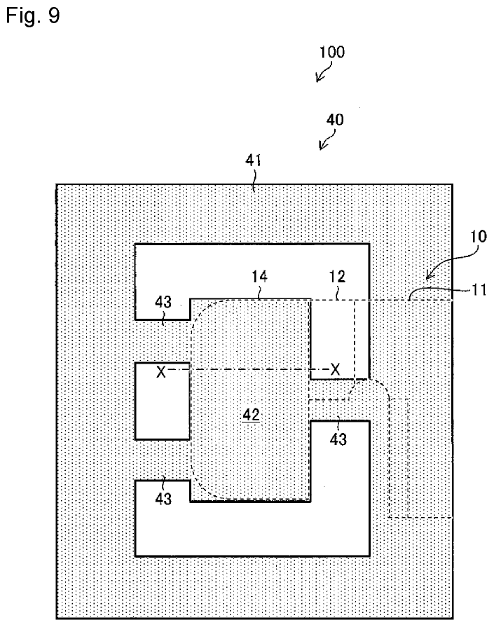

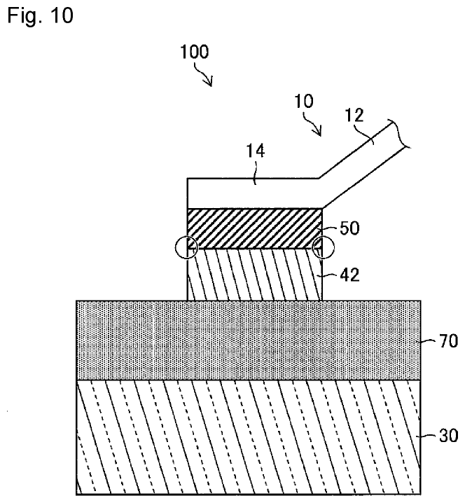

Now, the vehicle window glass with a metal terminal according to a second embodiment of the present invention will be described. Like reference numerals are used hereinafter and, in the drawings, to indicate members or parts identical or corresponding to those of the first embodiment. The explanation of those members or parts may be omitted. FIG. 9 is an enlarged view of the second embodiment. FIG. 10 is a cross-sectional view taken along line X-X of FIG. 9.

As shown in FIG. 9, the first pedestal portion 14 according to the second embodiment has a pedestal edge located just above the edge of a terminal connection portion 42. The second embodiment is different from the first embodiment in terms of this structure.

The conductor 40 includes the terminal connection portion 42, two coupling portions 43 connected to one of the opposite longer sides of the terminal connection portion 42, and a single coupling portion 43 connected to the other longer side. The conductor 40 includes the three coupling portions 43 in total. The three coupling portions 43 have the same width as one another.

The coupling portions 43 have a narrower width than the width of the terminal connection portion 42 in the longitudinal direction or the transverse direction as in the first embodiment. The conductor 40 includes a bus bar portion 41 having a greater width than at least portion of the coupling portions 43.

The entire pedestal edge of the first pedestal portion 14 needs not be located just above the edge of the terminal connection portion 42. At least 90% of the pedestal edge may be located just above the edge of the terminal connection portion 42.

In FIG. 10, it is shown that the vehicle window glass with a metal terminal 100 includes a glass plate 30, an optically shielding layer 70 disposed on the glass plate 30, the terminal connection portion 42 disposed on the optically shielding layer 70, and the first pedestal portion 14 of the metal terminal 10 electrically connected to the terminal connection portion 42 via the solder 50.

The solder 50 is formed in a rectangular shape as seen in cross-section since the pedestal edge of the first pedestal portion 14 is located just above the edge of the terminal connection portion 42. Thus, as shown in circles in FIG. 10, the edge of the terminal connection portion 42 can conform to the edge of the solder 50. By this arrangement, the optically shielding layer 70 disposed on a glass plate 30 or the conductor 40 disposed on the optically shielding layer 70 can be prevented from being cracked in several days after the optically shielding layer 70 is connected, via the lead-free solder, to the conductor 40. This arrangement can also prevent a surface of the glass plate under the optically shielding layer from partially peeling off. This arrangement can further secure a required bonding strength between the metal terminal 10 and the conductor 40 since the pedestal edge of the first pedestal portion 14 is located just above the edge of the terminal connection portion 42.

As shown in FIG. 9, the terminal connection portion 42 and the coupling portions 43 are connected together throughout at least 30% of the entire periphery of the terminal connection portion 42 as seen in plan view. When the size of the first pedestal portion 14 and the connection widths of the coupling portions 43 in the second embodiment are set at the same levels as those of the first embodiment, the entire periphery of the terminal connection portion 42 in the second embodiment becomes longer. In this case, the terminal connection portion 42 and the coupling portions 43 are connected together throughout at most 20% of the entire periphery of the terminal connection portion 42 as seen in plan view, for example.

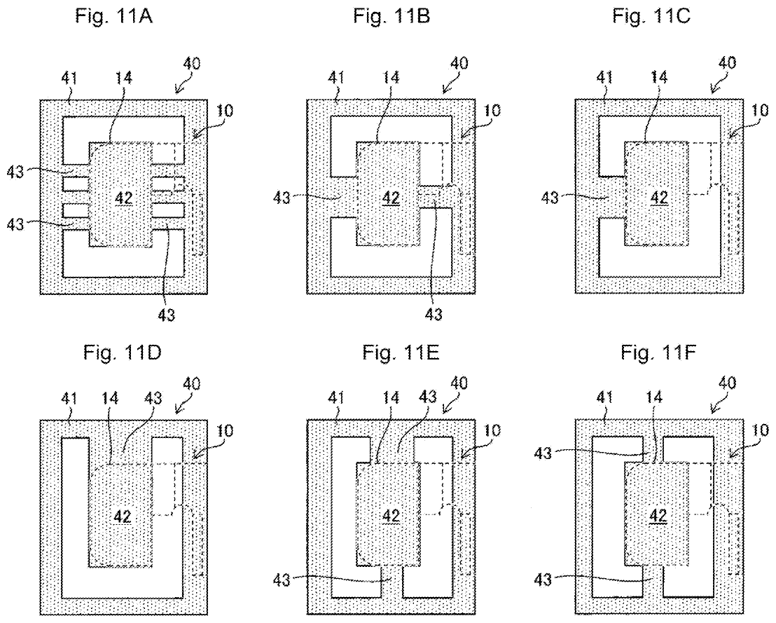

FIGS. 11A to 11F, and FIGS. 12G to 121 are plan views illustrating some modifications of the second embodiment. In the respective modifications shown in FIGS. 11A to 11F, and FIGS. 12G to 121, the pedestal edges of the first pedestal portions 14 are located just above the edges of the terminal connection portions 42.

In the modification shown in FIG. 11A, the conductor 40 includes a bus bar portion 41, a terminal connection portion 42, and three coupling portions 43 connected to each of the opposite longer sides of the terminal connection portion 42. The conductor 40 includes the six coupling portions 43 in total. The six coupling portions 43 have the same width as one another.

In the modification shown in FIG. 11B, the conductor 40 includes a bus bar portion 41, a terminal connection portion 42, and a coupling portion 43 connected to each of the opposite longer sides of the terminal connection portion 42. The conductor 40 includes the two coupling portions 43 in total. The two coupling portions 43 have different width from each other.

In the modification shown in FIG. 11C, the conductor 40 includes a bus bar portion 41, a terminal connection portion 42, and a single coupling portion 43 connected to one of the longer sides of the terminal connection portion 42.

As shown in FIG. 11D, the conductor 40 may include a bus bar portion 41, a terminal connection portion 42, and a single coupling portion 43 connected to one of the shorter sides of the terminal connection portion 42.

In the modification shown in FIG. 11E, the conductor 40 includes a bus bar portion 41, a terminal connection portion 42, and a coupling portion 43 connected to each of the opposite shorter sides of the terminal connection portion 42. The conductor 40 includes the two coupling portions 43 in total. The two coupling portions 43 have different widths from each other.

In the modification shown in FIG. 11F, the conductor 40 includes a bus bar portion 41, a terminal connection portion 42, and a coupling portion 43 connected to each of the opposite shorter sides of the terminal connection portion 42. The conductor 40 includes the two coupling portions 43 in total. The two coupling portions 43 have the same width as each other.

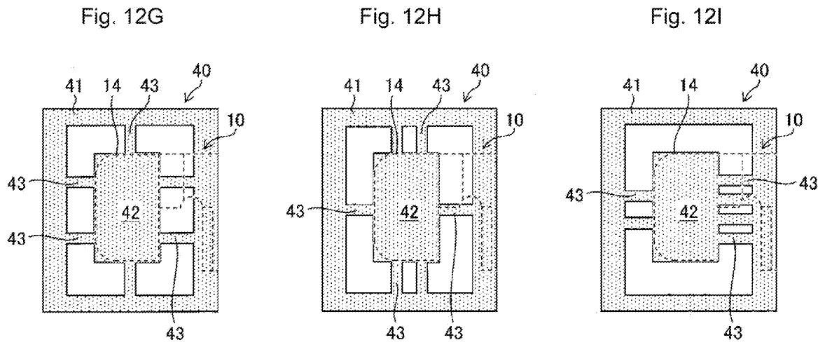

In the modification shown in FIG. 12G, the conductor 40 includes a bus bar portion 41, a terminal connection portion 42, two coupling portions 43 connected to each of the opposite longer sides of the terminal connection portion 42, and a coupling portion 43 connected to each of the opposite shorter sides of the terminal connection portion 42. The conductor 40 includes the six coupling portions 43 in total. The six coupling portions 43 have the same width as one another.

In the modification shown in FIG. 12H, the conductor 40 includes a bus bar portion 41, a terminal connection portion 42, two coupling portions 43 connected to each of the opposite shorter sides of the terminal connection portion 42, and a coupling portion 43 connected to each of the opposite longer sides of the terminal connection portion 42. The conductor 40 includes the six coupling portions 43 in total. The six coupling portions 43 have the same width as one another.

In the modification shown in FIG. 12I, the conductor 40 includes a bus bar portion 41, a terminal connection portion 42, two coupling portions 43 connected to one of the opposite longer sides of the terminal connection portion 42, and four coupling portions 43 to connected to the other longer side. The conductor 40 includes the six coupling portions 43 in total. The six coupling portions 43 have the same width as one another.

The terminal connection portions 42 according to the respective modifications shown in FIGS. 11A to 11F and FIGS. 12G to 121 have the same area as one another. The coupling portions according to the respective modifications shown in FIGS. 11A to 11F and FIGS. 12G to 121 have the same total area as one another.

Regarding the modifications shown in FIG. 9 to FIG. 12I, the first pedestal portion 14 has been described. The explanation of the first pedestal portion 14 according to each of the modifications is also applicable to the second pedestal portion 15. The explanation of the first pedestal portion 14 according to each of the modifications is also applicable to a metal terminal including a single pedestal portion or at least three pedestal portions, which is different from the metal terminal 10 including the two pedestal portions (the first pedestal portion 14 and the second pedestal portion 15).

The coupling structure between the terminal connection portion 42 and the coupling portions 43 is not limited to the examples shown in FIG. 11 and FIG. 12 and may be properly modified so long as the pedestal edge of the pedestal portion 14 is located just above the edge of the terminal connection portion 42.

### Third Embodiment

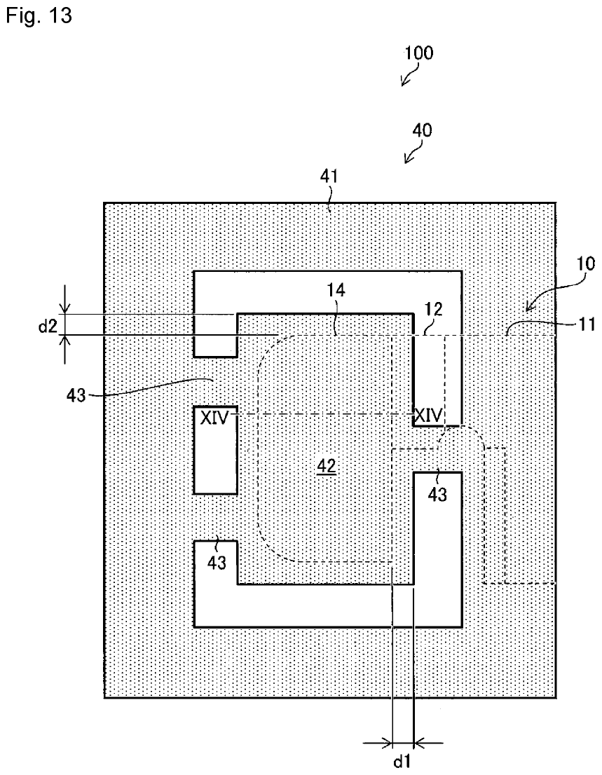

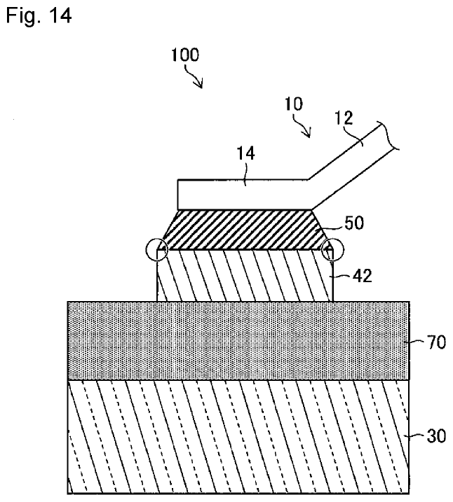

Now, the vehicle window glass with a metal terminal according to a third embodiment will be described. Like reference numerals are used hereinafter and, in the drawings, to indicate members or parts identical or corresponding to those of the first embodiment and the second embodiment. The explanation of these members or parts may be omitted. FIG. 13 is an enlarged view of the third embodiment. FIG. 14 is a cross-sectional view taken along line XIV-XIV of FIG. 13.

As shown in FIG. 13, the terminal connection portion 42 according to the third embodiment has an edge located not only outside the pedestal edge of a first pedestal portion 14 as seen in plan view but also less than 3 mm away from the pedestal edge forming the first pedestal portion 14 in a direction away from the first pedestal portion 14. This arrangement is different from that of the first embodiment and the second embodiment. In other words, the distance between the edge of the terminal connection portion 42 and the pedestal edge forming the first pedestal portion 14 is less than 3 mm. 43 connected to one of the opposite longer sides of the terminal connection portion 42, and a coupling portion 43 connected to the other longer side. The conductor 40 includes the three coupling portions 43 in total. The three coupling portions 43 have the same width as one another.

The coupling portions 43 have a narrower width than the width of the terminal connection portion 42 in the longitudinal direction or the traverse direction as in the first embodiment. The bus bar portion 41 of the conductor 40 has a greater width than at least portion of the coupling portions 43.

In FIG. 14 illustrating the third embodiment, it is shown that the vehicle window glass with a metal terminal 100 includes a glass plate 30, an optically shielding layer 70 disposed on the glass plate 30, a terminal connection portion 42 disposed on the optically shielding layer 70, and a first pedestal portion 14 of a metal terminal 10 electrically connected to the terminal connection portion 42 via the solder 50.

The solder 50 is formed in a substantially trapezoidal shape having a shorter top than a bottom as seen in cross-section because the edge of the terminal connection portion 14 is located less than 3 mm away from the pedestal edge forming the first pedestal portion 14 in a direction away from the first pedestal portion 14. This arrangement allows the edge of the terminal connection portion 42 to conform to the edge of the solder 50 as shown in circles in FIG. 14. By this arrangement, an optically shielding layer 70 disposed on the glass plate 30 or the conductor 40 disposed on the optically shielding layer 70 can be prevented from being cracked in several days after the optically shielding layer 70 is connected, via the lead-free solder, to the conductor 40. By this arrangement, a surface of the glass plate 30 under the optically shielding layer 70 can be prevented from partially peeling off. This arrangement can also secure a required bonding strength between the metal terminal 10 and the conductor 40 since the edge of the terminal connection portion 42 is located not only outside the pedestal edge of the first pedestal portion 14 but also less than 3 mm away from the pedestal edge forming the first pedestal portion 14 in the direction away from the first pedestal portion 14.

As shown in FIG. 13, in the third embodiment, the terminal connection portion 42 and the coupling portions 43 are connected together throughout at least 30% of the entire periphery of the terminal connection portion 42 as shown in plan view. When the size of the first pedestal portion 14 and the connection width of the coupling portions 43 are set at the same levels as those of the first embodiment and the second embodiment, the entire periphery of the terminal connection portion 42 becomes longer in the third embodiment. It results in that the terminal connection portion 42 and the coupling portions 43 are connected together at most 10% of the entire periphery of the terminal connection portion 42 as seen in plan view, for example.

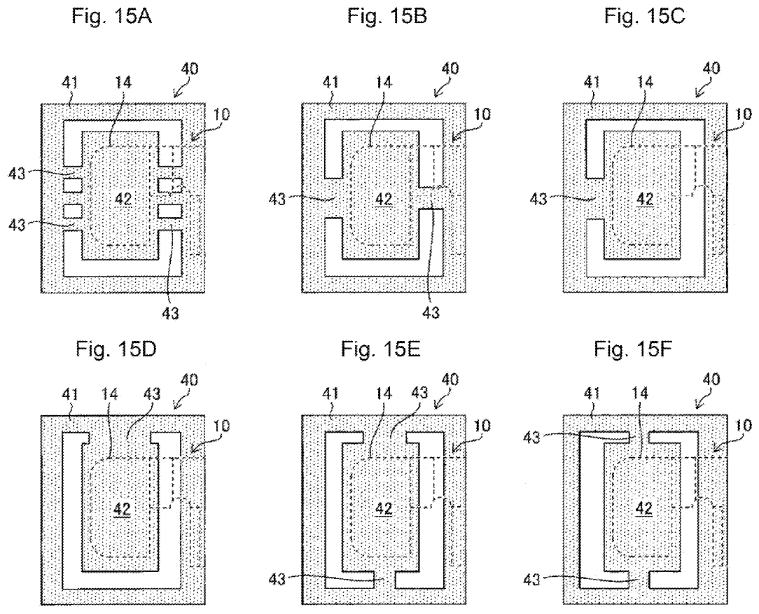

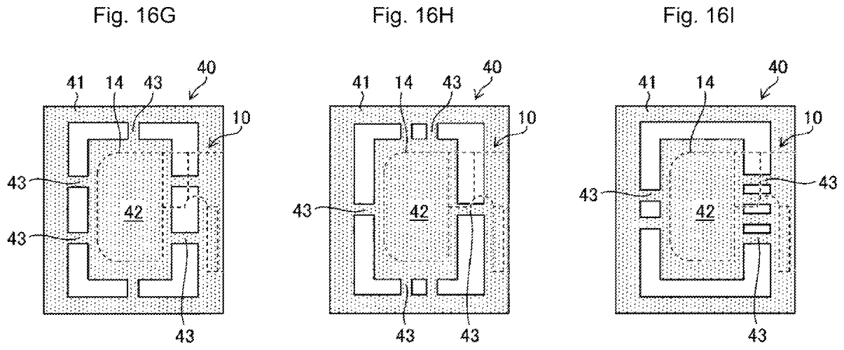

FIGS. 15A to 15F and FIGS. 16G to 16I are plan views illustrating some modifications of the third embodiment. In the respective modifications shown in FIGS. 15A to 15F and FIGS. 16G to 16I, the edges of the terminal connection portions 42 are located not only outside the pedestal edges of the first pedestal portion 14 but also less than 3 mm away from the pedestal edge forming the first pedestal portion 14 in the direction away from the first pedestal portion 14.

In the modification shown in FIG. 15A, the conductor 40 includes a bus bar portion 41, a terminal connection portion 42, and three coupling portions 43 connected to each of the opposite longer sides of the terminal connection portion 42. The conductor 40 includes the six coupling portions 43 in total. The six coupling portions 43 have the same width as one another.

In the modification shown in FIG. 15B, the conductor 40 includes a bus bar portion 41, a terminal connection portion 42, and a coupling portion 43 connected to each of the opposite longer sides of the terminal connection portion 42. The conductor 40 includes the two coupling portions 43 in total. The two coupling portions 43 have different widths from each other.

In the modification shown in FIG. 15C, the conductor 40 includes a bus bar portion 41, a terminal connection portion 42, and a single coupling portion 43 connected to one of the longer sides of the terminal connection portion 42.

In the modification shown in FIG. 15D, the conductor 40 includes a bus bar portion 41, a terminal connection portion 42, and a single coupling portion 43 connected to one of the shorter sides of the terminal connection portion 42.

In the modification shown in FIG. 15E, the conductor 40 includes a bus bar portion 41, a terminal connection portion 42, a coupling portion 43 connected to each of the opposite shorter sides of the terminal connection portion 42. The conductor 40 includes the two coupling portions 43 in total. The two coupling portions 43 have different widths from each other.

In the modification shown in FIG. 15F, the conductor 40 includes a bus bar portion 41, a terminal connection portion 42, and a coupling portion 43 connected to each of the opposite shorter sides of the terminal connection portion 42. The conductor 40 includes the two coupling portions 43 in total. The two coupling portions 43 have the same width as each other.

In the modification shown in FIG. 16G, the conductor 40 includes a bus bar portion 41, a terminal connection portion 42, two coupling portions 43 connected to each of the opposite longer sides of the terminal connection portion 42, and a coupling portion 43 connected to each of the opposite shorter sides of the terminal connection portion 42. The conductor 40 includes the six coupling portions 43 in total. The six coupling portions 43 have the same width as one another.

In the modification shown in FIG. 16H, the conductor 40 includes a bus bar portion 41, a terminal connection portion 42, two coupling portions 43 connected to each of the opposite shorter sides of the terminal connection portion 42, and a coupling portion 43 connected to each of the opposite longer sides of the terminal connection portion 42. The conductor 40 includes the six coupling portions 43 in total. The six coupling portions 43 have the same width as each other.

In the modification shown in FIG. 16I, the conductor 40 includes a bus bar portion 41, a terminal connection portion 42, two coupling portions 43 connected to one of the opposite longer sides of the terminal connection portion 42, and four coupling portions 43 connected to the other longer side. The conductor 40 includes the six coupling portions in total. The six coupling portions 43 have the same width as one another.

The terminal connection portions 42 according to the respective modifications shown in FIGS. 15A to 15F and FIGS. 16G to 16I have the same total area as one another. The coupling portions according to the respective modifications shown in FIGS. 15A to 15F and FIGS. 16G to 16I have the same total area as one another.

Regarding the modifications shown in FIG. 13 to FIG. 16I, the first pedestal portion 14 has been described. The explanation of the first pedestal portion 14 according to each of the modifications is also applicable to the second pedestal portion 15. The explanation of the first pedestal portion 14 according to each of the modifications is also applicable to a metal terminal including a single pedestal portion or at least three pedestal portions, which is different from the metal terminal 10 including the two pedestal portions (the first pedestal portion 14 and the second pedestal portion 15).

The coupling structure between the terminal connection portion 42 and the coupling portion or portions 43 is not limited to the examples shown in FIGS. 15A to 15F and FIGS. 16G to 16I and may be properly modified so long as the pedestal edge of the first pedestal portion 14 is located not only outside the pedestal edge of the first pedestal portion 14 but also less than 3 mm away from the pedestal edge forming the first pedestal portion 14.

### Fourth Embodiment

Now, the vehicle window glass with a metal terminal according to a fourth embodiment will be described. Like reference numerals are used hereinafter and, in the drawings, to indicate members or parts identical or corresponding to those of the first embodiment to the third embodiment. The explanation of those member or parts may be omitted.

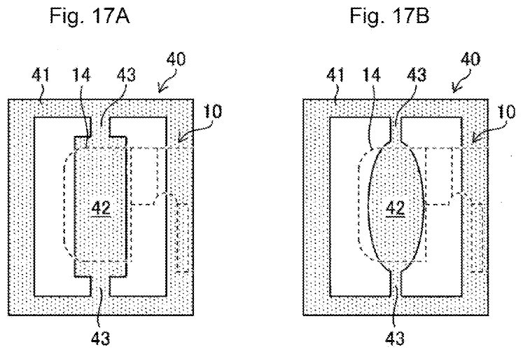

FIGS. 17A and 17B are enlarged views of the fourth embodiment. As shown in FIGS. 17A and 17B, the terminal connection portion 42 according to each modification of the fourth embodiment has an edge partly located not only outside the pedestal edge of the first pedestal portion 14 but also less than 3 mm away from the pedestal edge forming a first pedestal portion 14 in a direction away from the first pedestal portion 14.

On the other hand, the first pedestal portion 14 has an edge located outside the terminal connection portion 42 with respect to the remaining edge sections of the edge of the terminal connection portion 42.

In other words, the edge of the terminal connection portion 42 includes not only edge sections outside but also edge sections inside the first pedestal portion 14.

The terminal connection portion 42 shown in FIG. 17A is formed in a rectangular shape as seen in plan view. The terminal connection portion 42 has edge sections (shorter sides of the terminal connection portion) located outside the shorter sides of a first pedestal portion 14. On the other hand, the terminal connection portion 42 has the remaining edge portions (longer sides of the terminal connection portion) located inside the longer sides of the first pedestal portion 14. Coupling portions 43 are connected to both of the edge sections of the terminal connection portion 42 (shorter sides of the terminal connection portion) and a bus bar portion 41.

The terminal connection portion 42 shown in FIG. 17B is formed in an ellipsoidal shape as seen in plan view. The terminal connection portion 42 has edge sections (positioned in the major-axis direction) located outside the shorter sides of a first pedestal portion 14. On the other hand, the terminal connection portion 42 has the remaining edge sections (positioned in the minor-axis direction) located inside the longer sides of the first pedestal portion 14. Coupling portions 43 are connected to the edge sections of the terminal connection portion 42 (positioned in the major-axis direction).

Even the modifications formed as shown in FIGS. 17A and 17B can conform the edge of the terminal connection portion 42 to the edge of the solder 50 (not shown). By this arrangement, an optically shielding layer 70 disposed on a glass plate 30 or a conductor 40 disposed on the optically shielding layer 70 can be prevented from being cracked in several days after the optically shielding layer 70 is connected, via the lead-free solder, to the conductor 40. By this arrangement, a surface of the glass plate 30 under the optically shielding layer 70 can be prevented from partially peeling off. This arrangement can also secure a required bonding strength between the metal terminal 10 and the conductor 40 since the edge of the terminal connection portion 42 is partly located not only outside the pedestal edge of the first pedestal portion 14 but also less than 3 mm away from the pedestal edge forming the first pedestal portion 14 in the direction away from the first pedestal portion 14.

Regarding the respective modifications shown in FIGS. 17A and 17B, the first pedestal portion 14 has been described. The explanation of the first pedestal portion 14 is also applicable to the second pedestal portion 15 according to the modifications. The explanation of the first pedestal portion 14 is also applicable to a metal terminal including a single pedestal portion or at least three pedestal portions, which is different from the metal terminal 10 including the two pedestal portions (the first pedestal portion 14 and the second pedestal portion 15).

The coupling structure between the terminal connection portion 42 and the coupling portions 43 is not limited to the examples shown in FIGS. 17A and 17B and may be properly modified so long as the edge of the terminal connection portion 42 is partly located not only outside the pedestal edge portion of the first pedestal portion 14 but also less than 3 mm away from the pedestal edge portion forming the first pedestal portion 14 in the direction away from the first pedestal portion 14.

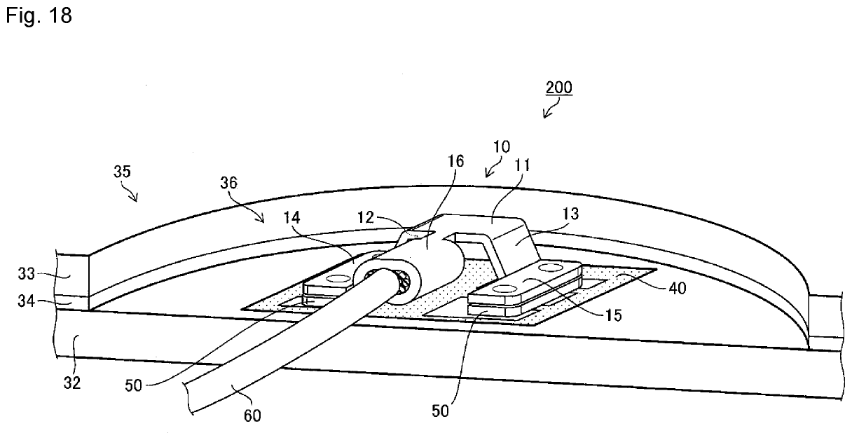

The vehicle window glass with a metal terminal according to another mode of the present invention will be described based on the accompanying drawings. As shown in FIG. 18, the vehicle window glass with a metal terminal 200 includes a laminated glass 35, which has an interlayer 34 bonding a first glass plate 32 and a second glass plate 33. The first glass plate 32 corresponds to the glass plate in each of the first embodiment to the fourth embodiment while the second glass plate 33 is an additional glass plate. The window glass with a metal terminal 200 is applicable to a vehicle windshield as one example. The first embodiment to the fourth embodiment are applicable to the vehicle window glass with a metal terminal 200 as in the vehicle window glass with a metal terminal 100. When the vehicle window glass with a metal terminal 200 is assembled in a vehicle body, the first glass plate 32 is disposed on an outer side of the vehicle body while the second glass plate 33 is disposed on an inner side of the vehicle body. The first glass plate 32 has an optically shielding layer 70 disposed on the interior surface, and the optically shielding layer 70 has a conductor 40 disposed thereon. It should be noted that the second glass plate 33 may correspond to the glass plate according to each of the first embodiment to the fourth embodiment while the first glass plate 32 may be an additional glass plate. When the second glass plate 33 serves as the glass plate according to each of the first embodiment to the fourth embodiment, and when the vehicle window glass with a metal terminal 200 is assembled in a vehicle body, the optically shielding layer 70 is disposed on the interior surface of the second glass plate 33 while the conductor 40 is disposed on the optically shielding layer 70.

The first glass plate 32 and the second glass plate 33 may be made of glass plates, which are identical or similar to the glass plates 30 according to the first embodiment to the fourth embodiment. In other words, each of the first glass plate 32 and the second glass plate 33 may be made of either non-tempered glass or tempered glass. The first glass plate 32 and the second glass plate 33 may have the same thickness as each other or different thicknesses from each other.

For example, the first glass plate 32 to be disposed on the outer side may have a thickness of preferably at least 1.1 mm and at most 3.0 mm. When the first glass plate 32 to be disposed on the outer side has a thickness of at least 1.1 mm, the first glass plate can have a sufficient strength in terms of strength against a flipped stone or the like. When the first glass plate has a thickness of at most 3.0 mm, the laminated glass 35 is prevented from having an excessively heavy weight, which is advantageous in terms of mileage of the vehicle. The first glass plate 32 to be disposed on the outer side may have a thickness of more preferably at least 1.5 mm and at most 2.8 mm, much more preferably at least 1.8 mm and at most 2.6 mm. The second glass plate 33 to be disposed on the inner side may have a thickness of preferably at least 0.5 mm and at most 2.3 mm. When the second glass plate 33 to be disposed on the inner side has a thickness of at least 0.5 mm, it is possible to have excellent handling. When the second glass plate disposed on the inner side has a thickness of at most 2.3 mm, the laminated glass is advantageously prevented from having an excessively heavy weight.

One or both of the first glass plate 32 and the second glass plate 33 may be formed in a wedge shape so as to have a thickness gradually increasing from a lower side (closer to the engine hood) toward an upper side (closer to the roof) when the laminated glass 35 is assembled into the vehicle body.

The first glass plate 32 and the second glass plate 33 may be formed in a plate shape by, e.g., a float process, and be bent at a high temperature by e.g., gravity bending to press bending. The laminated glass 35 may be formed in a complex shape so as to be curved in both of a longitudinal direction and a short direction. Or the laminated glass 35 may be a single curved shape so as to be curved only in the longitudinal direction or the short direction. When the laminated glass 35 is curved, the laminated glass is preferably curved so as to be convex toward the outer side. When the laminated glass 35 is curved, the laminated glass may have a radius curvature of preferably at least 1,000 mm and at most 100,000 mm. The first glass plate 32 and the second glass plate 33 may have the same radius curvature as each other or different radiuses of curvature from each other. When the first glass plate 32 and the second glass plate 33 have different radiuses of curvature, the first glass plate 32 has a larger radius of curvature than the second glass plate 33.

The interlayer 34 bonds the first glass plate 32 and the second glass plate 33. The interlayer 34 may be an interlayer made of polyvinyl butyral (PVB). When the interlayer is required to have water resistance, an interlayer made of an ethylene vinyl acetate copolymer (EVA) is preferable. An acrylic photopolymerizable prepolymer, an acrylic catalyst-polymerizable prepolymer, a photopolymerizable prepolymer of acrylate ester and vinyl acetate, or polyvinyl chloride is also applicable to the interlayer. The interlayer 34 may have a single layer structure or a multilayer structure.

The laminated glass 35 may have a dark and opaque optically shielding layer (not shown), such as a black optically shielding layer, disposed in a band shape on a peripheral edge portion throughout the entire periphery thereof. The optically shielding layer may be disposed on both of the first glass plate 32 and the second glass plate 33 or disposed on only one of them. The optically shielding layer has a function of protecting, from ultraviolet ray deterioration, a urethane sealant for bonding and holding the laminated glass 35 to the vehicle body.

In the vehicle window glass with a metal terminal 200, the second glass plate 33 has a cutout portion 36 formed in an arc shape in a peripheral edge portion so as to be through the second glass plate 33 in a thickness direction thereof. The first glass plate 32 has a conductor 40 disposed on the interior surface exposed by the cutout portion 36. When the optically shielding layer is disposed, the conductor 40 may be disposed on the optically shielding layer.

The first pedestal portion 14 and the second pedestal portion 15 of the metal terminal are electrically connected to the terminal connection portion 42 (not shown) of the conductor 40, which is disposed on the first glass plate 32 via the solder 50. The conductive wire 60 and the conductor 40 are electrically connected together via the metal terminal 10 and the solder 50.

The relationship between the terminal connection portion 42 and the pedestal portions (the first pedestal portion 14 and the second pedestal portion 15) in the vehicle window glass with a metal terminal 100 according to each of the first embodiment to the fourth embodiment is also applicable to the vehicle window glass with a metal terminal 200. By this relationship, the optically shielding layer 70 disposed on the glass plate 30 or the conductor 40 disposed on the optically shielding layer 70 can be prevented from being cracked in several days after the optically shielding layer 70 is connected to the conductor 40 via the lead-free solder. This relationship can also prevent a surface of the glass plate under the optically shielding layer 70 from partially peeling off. Further, this relationship can secure a required bonding strength between the metal terminal 10 and the conductor 40.

In the vehicle window glass with a metal terminal 100 according to the embodiment shown in FIG. 18 and the vehicle window glass with a metal terminal 200 according to each of the first embodiment to the fourth embodiment, the conductor 40 may include a plurality of bus bar portions 41 disposed, e.g., along a peripheral edge portion thereof, although not shown. In this case, the metal terminal 10 may be connected to the respective bus bar portions 41 and be further connected to the anode and the cathode of a power source. For example, a wire grid heater may be disposed between adjacent bus bar portions 41.

The wire grid heater may include fine wires made of tungsten for example. In this case, adjacent wires may be disposed so as to be apart from each other, or plural wires may be combined in a mesh pattern to cross with one another. Instead of the wire grid heater, a transparent conductive film may be disposed. Examples of the transparent conductive film include a metal film, such as an Ag film, a metal oxide film, such as an ITO (indium tin oxide) film, and a resin film containing fine conductive particles. The transparent conductive film may be prepared by stacking different kinds of films.

Now, some of the embodiments of the present invention have been described. The present invention is not limited to the described examples. Various improvements or modifications may be made without departing from the scope of the present invention. The vehicle window glass with a metal terminal is applicable to e.g., a windshield, a rear windshield, a side door glass and a quarter glass.

10: metal terminal, 11: leg connection portion, 12: first leg portion, 13: second leg portion, 14: first pedestal portion, 15: second pedestal portion, 16: conductive wire coupling portion, 16A: extending portion, 16B: fixing portion, 30: glass plate, 32: first glass plate, 33: second glass plate, 34: interlayer, 35: laminated glass, 36: cutout portion, 40: conductor, 41: bus bar portion, 42: terminal connection portion, 43: coupling portion, 50: solder, 60: conductive wire, 70: optically shielding layer, 100 and 200: vehicle window glass with a metal terminal

What is claimed is:

1. A vehicle window glass with a metal terminal, comprising:
a glass plate,
an optically shielding layer disposed on at least one of principal surfaces of the glass plate,
a conductor disposed on the optically shielding layer,
a metal terminal electrically connected to the conductor via a lead-free solder, and
a conductive wire configured to be fixed to the metal terminal;
wherein the metal terminal includes a pedestal portion;
wherein the conductor includes a terminal connection portion connected to the pedestal portion by means of the lead-free solder, and a coupling portion connected to the terminal connection portion and having a narrower width than a width of the terminal connection portion in a longitudinal direction or a transverse direction of the terminal connection portion;
wherein the terminal connection portion and the coupling portion are connected together throughout at most 30% of an entire periphery of the terminal connection portion as seen in plan view; and
wherein the terminal connection portion has an edge located less than 3 mm away from a pedestal edge forming the pedestal portion in a direction away from the pedestal portion.

2. The vehicle window glass with a metal terminal according to claim 1, wherein the pedestal edge of the pedestal portion is located just above the edge of the terminal connection portion.

3. The vehicle window glass with a metal terminal according to claim 1, wherein the pedestal edge of the pedestal portion is disposed outside the edge of the terminal connection portion.

4. The vehicle window glass with a metal terminal according to claim 1, wherein the conductor includes a bus bar portion having a greater width than at least one portion of the coupling portion; and
wherein the bus bar portion is connected to the terminal connection portion by the coupling portion.

5. The vehicle window glass with a metal terminal according to claim 2, wherein the conductor includes a bus bar portion having a greater width than at least one portion of the coupling portion; and
wherein the bus bar portion is connected to the terminal connection portion by the coupling portion.

6. The vehicle window glass with a metal terminal according to claim 3, wherein the conductor includes a bus bar portion having a greater width than at least one portion of the coupling portion; and
wherein the bus bar portion is connected to the terminal connection portion by the coupling portion.

7. The vehicle window glass with a metal terminal according to claim 1, wherein the metal terminal comprises at least one selected from the group consisting of copper, brass, iron, chromium, and an alloy including copper, brass, iron and chromium.

8. The vehicle window glass with a metal terminal according to claim 1, wherein the glass plate comprises tempered glass.

9. The vehicle window glass with a metal terminal according to claim 1, wherein the glass plate comprises non-tempered glass.

10. The vehicle window glass with a metal terminal according to claim 1, wherein the lead-free solder has an Sn (tin) content of at least 95 mass %.

11. The vehicle window glass with a metal terminal according to claim 1, wherein the vehicle window glass comprises a laminated glass having a first glass plate, an interlayer, and a second glass plate bonded to the first glass plate by the interlayer.

12. The vehicle window glass with a metal terminal according to claim 11, wherein the second glass plate has a cutout portion formed therein so as to be therethrough in a thickness direction thereof; and wherein the metal terminal is disposed on a surface of the first glass plate exposed by the cutout portion.

13. The vehicle window glass with a metal terminal according to claim 11, configured to be assembled in a vehicle such that the first glass plate is disposed on an outer side of the vehicle while the second glass plate is disposed on an inner side of the vehicle.

14. The vehicle window glass with a metal terminal according to claim 13, configured to be assembled in a vehicle such that the first glass plate is disposed on an outer side of the vehicle while the second glass plate is disposed on an inner side of the vehicle.

15. The vehicle window glass with a metal terminal according to claim 11, configured to be assembled in a vehicle such that the first glass plate is disposed on an inner side of the vehicle while the second glass plate is disposed on an outer side of the vehicle.
